(19) United States
(12) Patent Application Publication
(10) Pub. No.: US 2010/0079637 A1
(43) Pub. Date: Apr. 1, 2010

(54) Image Sensor and Method For Manufacturing the Same

(76) Inventor: JOON HWANG, Chungbuk (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/566,772

(22) Filed: Sep. 25, 2009

(30) Foreign Application Priority Data
Sep. 30, 2008 (KR) 10-2008-0096074

(51) Int. Cl. H04N 5/335; H01L 31/18

(52) U.S. Cl. 348/294; 438/98; 348/E05.091; 257/E21.585

(57) ABSTRACT

Provided is an image sensor that comprises a readout circuitry, an electrical junction region, an interconnection, and an image sensing device. The readout circuitry is disposed at a first substrate. The electrical junction region is electrically connected to the readout circuitry at the first substrate. The interconnection is disposed in an interlayer dielectric disposed on the first substrate, and electrically connected to the electrical junction region. The image sensing device comprises a first conductive type layer and a second conductive type layer on the interconnection. The first conductive type layer is electrically connected to the interconnection through a contact plug passing through the image sensing device.

### CROSS-REFERENCE TO RELATED APPLICATION

This application claims the benefit under 35 U.S.C. §119 of Korean Patent Application No. 10-2008-0096074, filed Sep. 30, 2008, which is hereby incorporated by reference in its entirety.

### BACKGROUND

The present disclosure relates to an image sensor and a method for manufacturing the same.

An image sensor is a semiconductor device for converting an optical image into an electric signal. The image sensor may be roughly classified into a charge coupled device (CCD) image sensor and a complementary metal oxide semiconductor (CMOS) image sensor (CIS).

During the fabrication of image sensors, a photodiode may be formed in a substrate using ion implantation. As the size of a photodiode is reduced for the purpose of increasing the number of pixels without increasing chip size, the area of a light receiving portion is also reduced, thereby resulting in a reduction in image quality.

Also, since a stack height does not reduce as much as the reduction in the area of the light receiving portion, the number of photons incident to the light receiving portion is also reduced due to diffraction of light called Airy disk.

As an alternative to overcome this limitation, an attempt of forming a photodiode using amorphous silicon (Si), or forming a readout circuitry in a silicon (Si) substrate using a method such as wafer-to-wafer bonding, and forming a photodiode on and/or over the readout circuitry has been made (referred to as a three-dimensional (3D) image sensor). The photodiode is connected with the readout circuitry through a metal interconnection.

In the related art, because both the source and the drain of the transfer transistor are heavily doped with N-type impurities, a charge sharing phenomenon occurs. When the charge sharing phenomenon occurs, the sensitivity of an output image is reduced and an image error may be generated.

Also, because a photo charge does not readily move between the photodiode and the readout circuitry, a dark current is generated and/or saturation and sensitivity is reduced.

In addition, a contact plug connecting the readout circuitry and the photodiode may cause a short in the photodiode.

### BRIEF SUMMARY

Embodiments provide an image sensor where a charge sharing does not occur while increasing a fill factor, and a method for manufacturing the same.

Embodiments also provide an image sensor that can minimize a dark current source and inhibit saturation reduction and sensitivity degradation by forming a smooth transfer path of a photo charge between a photodiode and a readout circuitry, and a method for manufacturing the same.

Embodiments also provide an image sensor that can inhibit a short at a contact plug connecting a readout circuitry and an image sensing device, and a method for manufacturing the same.

In one embodiment, an image sensor comprises: a readout circuitry at a first substrate; an electrical junction region electrically connected to the readout circuitry at the first substrate; an interconnection in an interlayer dielectric disposed on the first substrate, the interconnection being electrically connected to the electrical junction region; and an image sensing device comprising a first conductive type layer and a second conductive type layer on the interconnection. A contact plug connects the first conductive type layer to the interconnection through a via hole passing through the image sensing device and a sidewall dielectric is disposed on a sidewall of the second conductive type layer corresponding to the via hole to electrically isolate the contact plug from the second conductive type layer.

In another embodiment, a method for manufacturing an image sensor comprises: forming a readout circuitry at a first substrate; forming an electrical junction region electrically connected to the readout circuitry at the first substrate; forming an interlayer dielectric on the first substrate to form an interconnection in the interlayer dielectric, the interconnection being electrically connected to the electrical junction region; and forming an image sensing device comprising a first conductive type layer and a second conductive type layer on the interlayer dielectric. An initial via hole is formed penetrating a portion of the image sensing device and a sidewall dielectric may be formed at sidewalls of the second conductive type layer in the initial via hole. A secondary via hole is formed through the image sensing device to expose the interconnection, and a contact plug is formed to electrically connect the first conductive type layer to the interconnection.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view illustrating an image sensor according to a first embodiment.

FIGS. 2 to 12 are cross-sectional views illustrating a method for manufacturing the image sensor, according to the first embodiment.

FIGS. 13 to 14 are cross-sectional views illustrating a method for manufacturing an image sensor, according to a second embodiment.

FIG. 15 is a cross-sectional view illustrating an image sensor according to a third embodiment.

### DETAILED DESCRIPTION

Hereinafter, embodiments of an image sensor and a method for manufacturing the same will be described with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

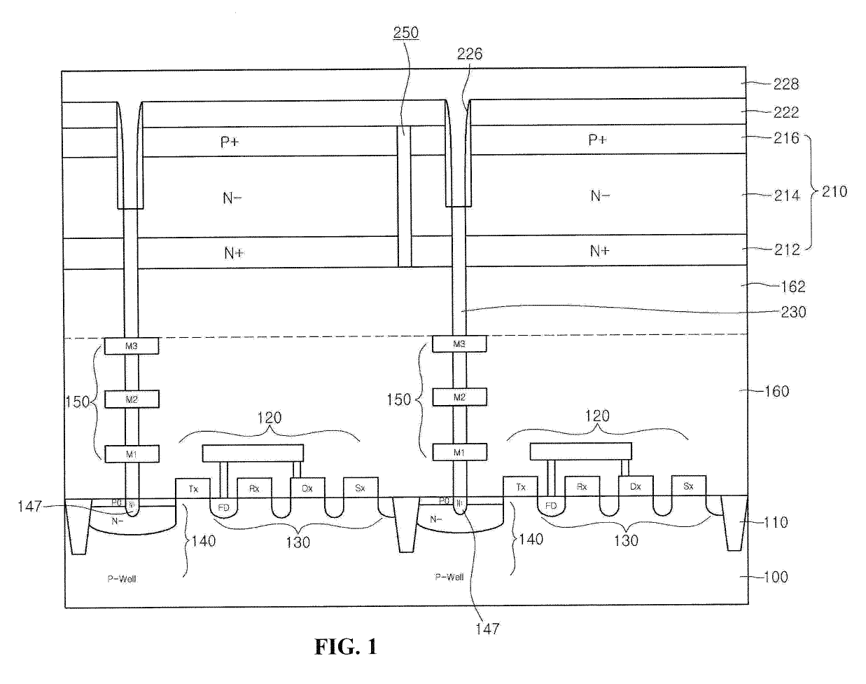

FIG. 1 is a cross-sectional view illustrating an image sensor according to a first embodiment.

The image sensor according to the first embodiment may include: a readout circuitry 120 at a first substrate 100; an electrical junction region 140 electrically connected to the readout circuitry 120 at the first substrate 100; an interconnection 150 disposed in a first interlayer dielectric 160 disposed on the first substrate 100 and electrically connected to the electrical junction region 140; a second interlayer dielectric 162 disposed on the interconnection 150; and an image sensing device 210 including a first conductive type layer 214 and a second conductive type layer 216 on the second interlayer dielectric 162.

The image sensor according to the first embodiment may further include: a contact plug 230 connecting the first conductive type layer 214 to the interconnection 150 through a via hole passing through the image sensing device 210; and a sidewall dielectric 226 disposed on a sidewall of the second conductive type layer 216 corresponding to the via hole.

The image sensing device 210 may be a photodiode, but, without being limited thereto, may be a photogate, or a combination of the photodiode and the photogate. Embodiments include a photodiode formed in a crystalline semiconductor layer as an example. However, embodiments are not limited thereto, and may include, for example, a photodiode formed in amorphous semiconductor layer.

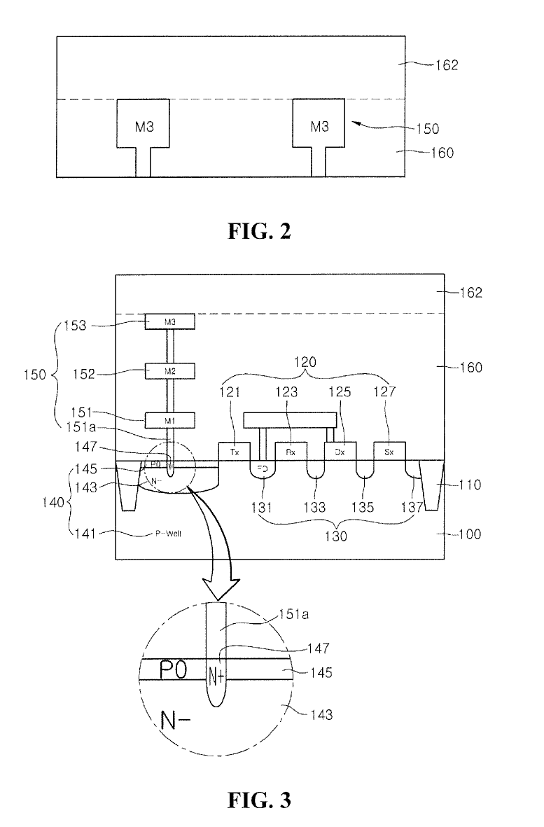

Hereinafter, a method for manufacturing the image sensor according to the first embodiment will be described with reference to FIGS. 2 to 12.

FIG. 2 is a schematic view illustrating the first substrate 100 provided with the interconnection 150 and a readout circuitry. FIG. 3 is a detailed view of FIG. 2. Hereinafter, a description will now be made on the basis of FIG. 3.

As illustrated in FIG. 3, an active region is defined by forming a device isolation layer 110 in the first substrate 100. The readout circuitry 120 may include a transfer transistor (Tx) 121, a reset transistor (Rx) 123, a drive transistor (Dx) 125, and a select transistor (Sx) 127. An ion implantation region 130, including a floating diffusion region (FD) 131 and a source/drain region 133, 135 and 137 for each transistor, may be formed.

According to an embodiment, the electrical junction region 140 can be formed on the first substrate 100, and a first conductive type connection 147 can be formed connected to the interconnection 150 at an upper part of the electrical junction region 140.

For example, the electrical junction region 140 may be a P-N junction 140, but is not limited thereto. For example, the electrical junction region 140 may include a first conductive type ion implantation layer 143 formed on a second conductive type well 141 or a second conductive type epitaxial layer, and a second conductive type ion implantation layer 145 formed on the first conductive type ion implantation layer 143. For example, as shown in FIG. 3, the P-N junction 140 may be a P0(145)/N−(143)/P−(141) junction, but embodiments are not limited thereto. The first substrate 100 may be a second conductive type substrate, but is not limited thereto.

According to an embodiment, the device is designed to provide a potential difference between the source and drain of the transfer transistor (Tx), thereby enabling the full dumping of a photo charge. Accordingly, a photo charge generated in the photodiode is dumped to the floating diffusion region, thereby increasing the output image sensitivity.

That is, as shown in FIG. 3, the electrical junction region 140 is formed in the first substrate 100 including the readout circuit 120 to provide a potential difference between the source and drain of the transfer transistor (Tx) 121, thereby implementing the full dumping of a photo charge.

Specifically, electrons generated in the photodiode 210 are transferred to the PNP junction 140, and they are transferred to the floating diffusion (FD) 131 node to be converted into a voltage when the transfer transistor (Tx) 121 is turned on.

The maximum voltage of the P0/N−/P− junction 140 becomes a pinning voltage, and the maximum voltage of the FD 131 node becomes Vdd minus the threshold voltage (Vth) of the reset transistor (Rx). Therefore, due to a potential difference between the source and drain of the Tx 121, without charge sharing, electrons generated in the photodiode 210 on the chip can be completely dumped to the FD 131 node.

Thus, unlike the related art case of connecting a photodiode simply to an N+ junction, an embodiment of the present invention makes it possible to inhibit saturation reduction and sensitivity degradation.

The first conductive type connection 147 can be formed between the photodiode and the readout circuit to create a smooth transfer path of a photo charge, thereby making it possible to minimize a dark current source and inhibit saturation reduction and sensitivity degradation.

To this end, the first embodiment may form an N+ doping region as the first conductive type connection 147 for an ohmic contact on the surface of the P0/N−/P− junction 140. The N+ region (147) may be formed such that it penetrates the P0 region (145) to contact the N− region (143).

The width of the first conductive type connection 147 may be minimized to inhibit the first conductive type connection 147 from being a leakage source. To this end, a plug implant may be performed after etching a contact hole for a first metal contact 151a, but embodiments are not limited thereto. As another example, an ion implantation pattern (not shown) may be formed, and the ion implantation pattern may be used as an ion implantation mask to form the first conductive type connection 147.

Next, the interlayer dielectric 160 may be formed on the first substrate 100, and the interconnection 150 may be formed. The interconnection 150 may include the first metal contact 151a, a first metal 151, a second metal 152, and a third metal 153, but embodiments are not limited thereto.

The second interlayer dielectric 162 is formed on the interconnection 150. For example, the second interlayer dielectric 162 may be formed of a dielectric such as an oxide layer or a nitride layer. The second interlayer dielectric 162 increases bonding force of a second substrate (not shown) provided with the image sensing device 210 and the first substrate 100.

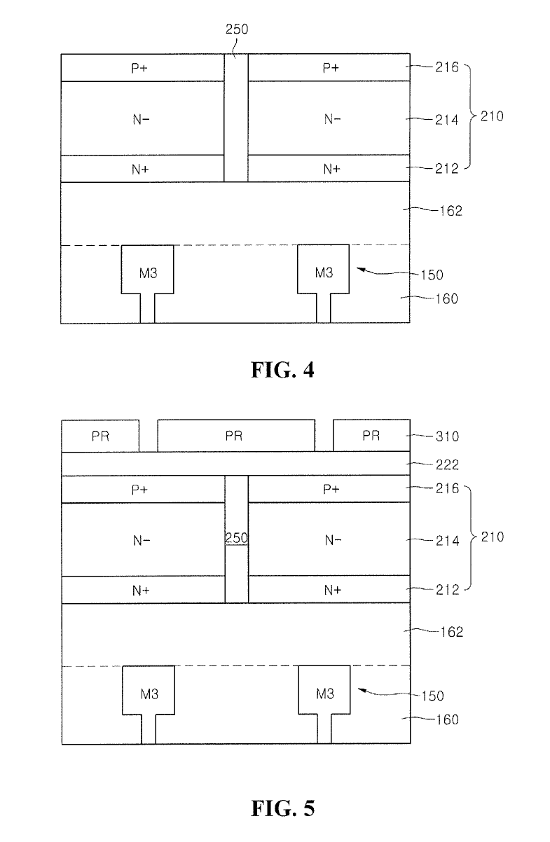

Referring to FIG. 4, the image sensing device 210 including the first conductive type layer 214 and the second conductive type layer 216 is formed on the second interlayer dielectric 162.

For example, a crystalline semiconductor layer of a second substrate (not shown) may be provided with the photodiode including the N− layer (214) and the P+ layer (216). An N+ layer of a first conductive type layer 212 for an ohmic contact may be further provided. According to an embodiment, the thickness of the first conductive type layer 214 is greater than that of the second conductive type layer 216, so as to increase charge storing capacity.

Once the second substrate is bonded to the first substrate and the photodiode is exposed on the first substrate, an etching process, dividing the image sensing device 210 by pixel, is performed to fill etched portions between pixels with an inter-pixel separation layer 250. In an embodiment, the inter-pixel separation layer 250 may be formed of a dielectric such as an oxide layer, but embodiments are not limited thereto. For example, the inter-pixel separation layer 250 may be formed through ion implantation. In another embodiment, the inter-pixel separation layer 250 may be formed after forming the contact plug 230.

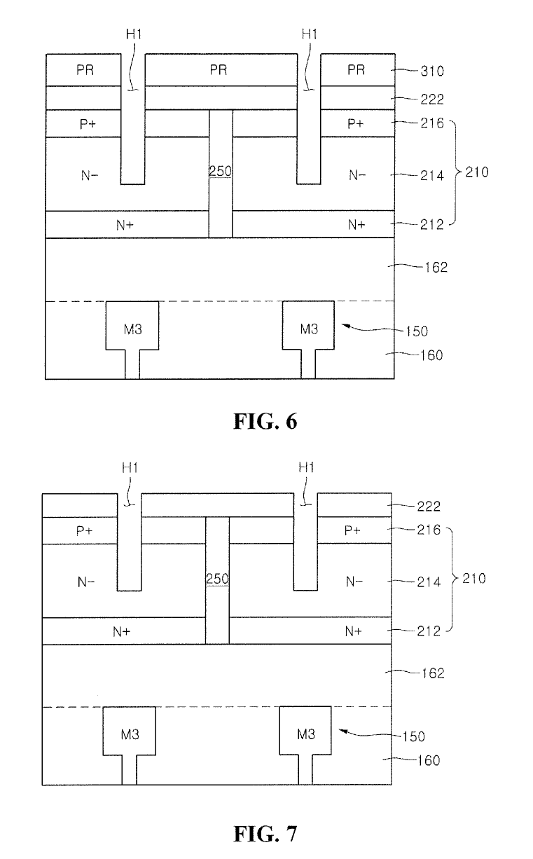

Referring to FIG. 5, a first dielectric 222 is formed on the image sensing device 210, and a photoresist pattern 310 for forming first via holes H1 (refer to FIG. 6) is formed. For example, the first dielectric 222 may include an oxide layer or a nitride layer, but embodiments are not limited thereto.

Referring to FIG. 6, the first via holes H1 are formed by partially removing the second conductive type layer 216 of the image sensing device 210. For example, the first via holes H1 may be formed by partially removing the P+ layer (216) using the photoresist pattern 310 as an etch mask, so as to expose the N− layer (214). The first via holes H1 may have a depth to pass through the second conductive type layer 216, but not to reach the high concentration first conductive type layer 212.

Referring to FIG. 7, the photoresist pattern 310 is removed.

Referring to FIG. 8, a sidewall dielectric 226 is formed on the sidewall of the second conductive type layer 216. For example, a second dielectric 224 such as an oxide layer is formed at the first via holes H1. Then, a blanket etch, such as an etch back process, may be performed on the second dielectric 224 to form the sidewall dielectric 226 on the sidewall of the second conductive type layer 216.

According to the first embodiment, the contact plug 230 passing through the image sensing device 210 is insulated using the sidewall dielectric 226 to avoid a short at the contact plug 230 connecting the readout circuitry 120 and the image sensing device 210.

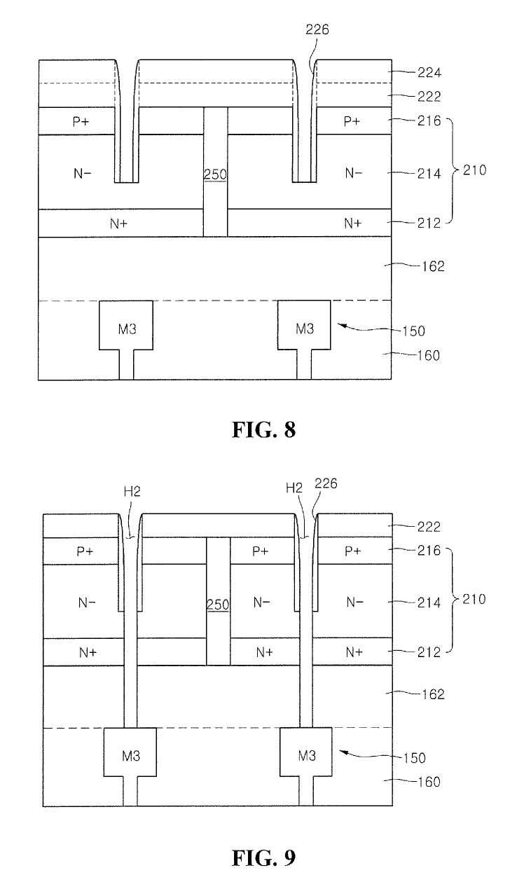

Referring to FIG. 9, second via holes 112, passing through the first via holes H1 to expose the interconnection 150, are formed using the sidewall dielectric 226 as an etch mask. For example, the second via holes H2 passing through the image sensing device 210 and the second interlayer dielectric 162 to expose the upper portion of the interconnection 150 may be formed.

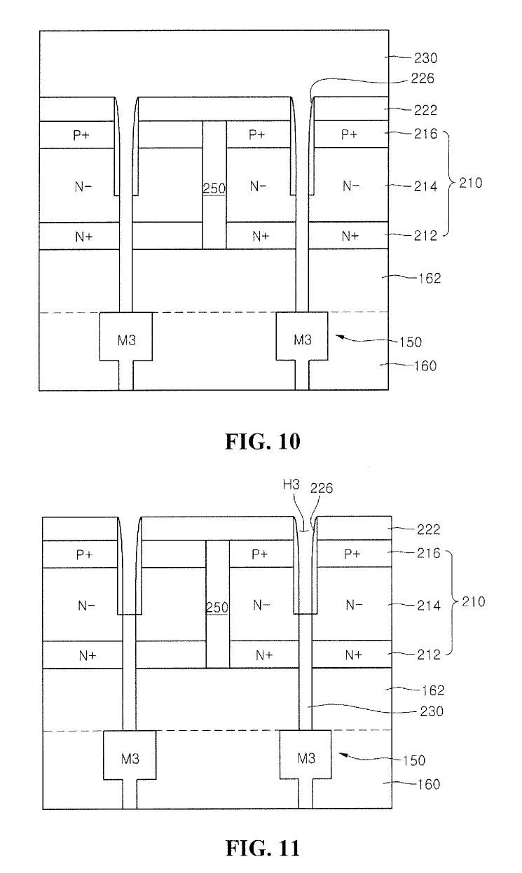

Referring to FIG. 10, a contact plug 230, connecting the first conductive type layer 214 and the interconnection 150, may be formed at the second via holes H2. For example, the contact plug 230, filling the second via holes H2, may be formed of metal such as tungsten (W) and titanium (Ti).

Referring to FIG. 11, a portion of the contact plug 230 at a region corresponding to the second conductive type layer 216 may be removed to form third via holes H3. For example, a portion of the contact plug 230 at a region corresponding to the P+ layer (216) may be removed through a blanket etch.

Referring to FIG. 12, a third dielectric 228 may be formed in the third via holes H3. For example, the third dielectric 228 formed at the third via holes H3 may be an oxide layer.

After that, a ground process may be performed on the second conductive type layer 216.

According to the first embodiment, the contact plug 230 passing through the image sensing device 210 is insulated using the sidewall dielectric 226 to avoid a short at the contact plug 230 connecting the readout circuitry 120 and the image sensing device 210.

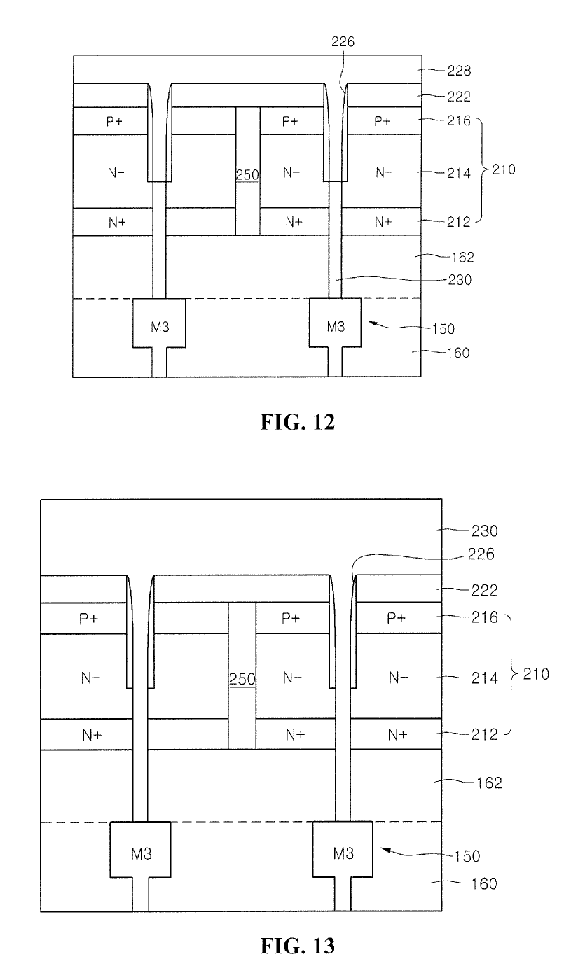

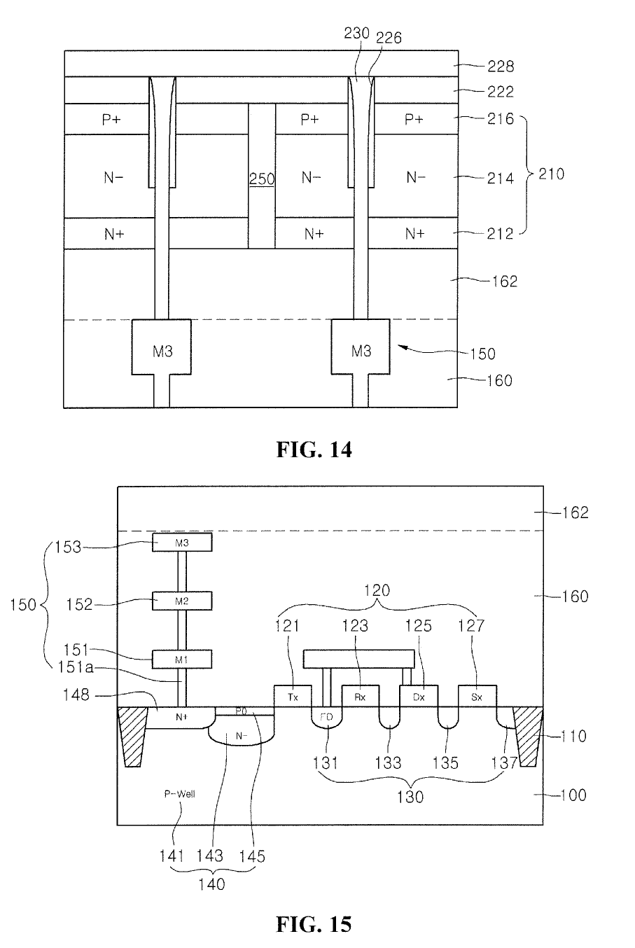

FIGS. 13 and 14 are cross-sectional views illustrating a method for manufacturing an image sensor according to a second embodiment.

The second embodiment may adopt the technical features of the first embodiment.

Hereinafter, differences between the first and second embodiments will now be described in detail.

Referring to FIG. 13, the contact plug 230 is formed at the first via holes H1 by filling the second via holes H2 with metal (similarly to the step described with respect to FIG. 10).

Referring to FIG. 14, according to the second embodiment, the material used to form the contact plug 230 is removed from the upper side of the image sensing device 210, while remaining in the entire second via hole H2. Then, the third dielectric 228 may be formed on the contact plug 230, and a ground process may be performed on the second conductive type layer 216.

According to the second embodiment, the contact plug 230 is electrically insulated from the second conductive type layer 216 through the sidewall dielectric 226. Thus, even when only the portion of the contact plug 230 corresponding to the upper side of the image sensing device 210 is removed, a short is avoided and manufacturing efficiency is improved.

FIG. 15 is a cross-sectional view illustrating an image sensor according to a third embodiment. The first substrate 100 provided with the interconnection 150 is illustrated in detail.

The third embodiment may adopt the technical features of the first embodiment and the second embodiment.

The third embodiment is different from the first embodiment in that a first conductive type connection 148 is connected to a side of the electrical junction region 140.

The N+ connection region 148 may be formed at the P0/N−/P− junction 140 for an ohmic contact. In this case, a leakage source may be generated during the formation process of the N+ connection region 148 and the M1C contact 151a. Also, when the N+ connection region 148 is formed over the surface of the P0/N−/P− junction 140, an electric field may be additionally generated due to N+/P0 junction 148/145. This electric field may also become a leakage source.

Therefore, the third embodiment proposes a layout in which the first contact plug 151a is formed in an active region not doped with a P0 layer, but rather includes an N+ connection region 148 that is electrically connected to the N-junction 143.

According to the third embodiment, the electric field is not generated on and/or over a Si surface, thereby contributing to reduction in a dark current of a 3D integrated CIS.

According to the embodiment, the electrical junction region is formed in the first substrate including the readout circuit to provide a potential difference between the source and drain of the transfer transistor (Tx), thereby implementing the full dumping of a photo charge.

In addition, according to the embodiment, the first conductive type connection can be formed between the photodiode and the readout circuit to create a smooth transfer path of a photo charge, thereby making it possible to minimize a dark current source and inhibit saturation reduction and sensitivity degradation.

According to the embodiment, the contact plug passing through the image sensing device is insulated using the sidewall dielectric to avoid a short at the contact plug connecting the readout circuitry and the image sensing device.

Any reference in this specification to “one embodiment,” “an embodiment,” “the embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a readout circuitry at a first substrate;
an electrical junction region electrically connected to the readout circuitry at the first substrate;
an interconnection in an interlayer dielectric disposed on the first substrate, the interconnection being electrically connected to the electrical junction region;
an image sensing device comprising a first conductive type layer and a second conductive type layer on the interconnection;
a contact plug connecting the first conductive type layer to the interconnection through a via hole passing through the image sensing device; and
a sidewall dielectric on a sidewall of the second conductive type layer corresponding to the via hole.

2. The image sensor according to claim 1, wherein the electrical junction region comprises:
a first conductive type ion implantation region at the first substrate; and
a second conductive type ion implantation region on the first conductive type ion implantation region.

3. The image sensor according to claim 1, wherein the readout circuitry comprises a transistor, wherein the electrical junction region is disposed at a source of the transistor, whereby a potential difference is provided between the source and a drain of the transistor.

4. The image sensor according to claim 1, further comprising a first conductive type connection between the electrical junction region and the interconnection, the first conductive type connection electrically connecting the electrical junction to the interconnection.

5. The image sensor according to claim 4, wherein the first conductive type connection is disposed at an upper part of the electrical junction region.

6. The image sensor according to claim 4, wherein the first conductive type connection is disposed at a side of the electrical junction region.

7. The image sensor according to claim 1, further comprising a third dielectric filling the via hole on the sidewall dielectric,
wherein the contact plug is in contact with the first conductive type layer.

8. The image sensor according to claim 1, wherein the sidewall dielectric is disposed between the contact plug and the second conductive type layer, and the contact plug has a height to reach an upper side of the second conductive type layer.

9. The image sensor according to claim 8, further comprising a third dielectric on the contact plug.

10. A method for manufacturing an image sensor, the method comprising:
forming a readout circuitry at a first substrate;
forming an electrical junction region electrically connected to the readout circuitry at the first substrate;
forming an interlayer dielectric on the first substrate and an interconnection in the interlayer dielectric, the interconnection being electrically connected to the electrical junction region;
forming an image sensing device comprising a first conductive type layer and a second conductive type layer on the interlayer dielectric; and
partially removing the second conductive type layer of the image sensing device to form a first via hole;
forming a sidewall dielectric on a sidewall of the second conductive type layer;
partially etching the first conductive type layer and the interlayer dielectric using the sidewall dielectric as an etch mask, so as to form a second via hole exposing the interconnection; and
forming a contact plug electrically connecting the first conductive type layer to the interconnection through the second via hole.

11. The method according to claim 10, wherein the forming of the electrical junction region comprises:
forming a first conductive type ion implantation region at the first substrate; and
forming a second conductive type ion implantation region on the first conductive type ion implantation region.

12. The method according to claim 10, wherein the readout circuitry comprises a transistor, wherein the electrical junction region is formed at a source of the transistor, whereby a potential difference is provided between the source and a drain of the transistor.

13. The method according to claim 10, further comprising forming a first conductive type connection between the electrical junction region and the interconnection to electrically connect the electrical junction region to the interconnection.

14. The method according to claim 10, wherein the forming of the sidewall dielectric comprises:
forming a second dielectric at the first via hole; and
blanket-etching the second dielectric.

15. The method according to claim 10, further comprising, after the forming of the contact plug:
removing a portion of the contact plug at a region corresponding to the second conductive type layer to form a third via hole; and
forming a third dielectric in the third via hole.

16. The method according to claim 10, further comprising, after the forming of the contact plug:
removing a portion of the contact plug corresponding to an upper side of the image sensing device; and
forming a third dielectric on the contact plug.
